(19) United States
(12) Patent Application Publication
(10) Pub. No.: US 2025/0359141 A1
(43) Pub. Date: Nov. 20, 2025

(54) SIC MOSFET WITH IMPROVED BURIED CONTACT STRUCTURE

(71) Applicant: Renesas Design (UK) Limited, London (GB)

(72) Inventors: Meng Chia LEE, Campbell, CA (US); Dilip Madhav RISBUD, Campbell, CA (US)

(21) Appl. No.: 18/664,088

(22) Filed: May 14, 2024

(51) Int. Cl. H01L 29/78; H01L 29/10; H01L 29/16; H01L 29/66

(52) U.S. Cl. CPC H10D 30/668; H10D 30/0297; H10D 62/393; H10D 62/8325

(57) ABSTRACT

A vertical silicon carbide transistor is provided in which a body contact and a source contact are both formed at an upper surface of a silicon carbide layer. The source contact and the body contact are wet etched so that a sidewall of the etched source contact is spaced apart and above an upper surface of the etched body contact. A silicide layer forms a buried contact to the body contact and also couples to the sidewall of the source contact.

### TECHNICAL FIELD

The present invention relates to metal-oxide semiconductor field effect transistors (MOSFETs), and more particularly to a silicon carbide (SiC) MOSFET with an improved buried contact structure.

### BACKGROUND

Silicon-based power switch transistors have been traditionally used in switching power supplies but are limited by the relatively narrow bandgap of silicon, low thermal conductivity and breakdown voltage. As compared to silicon, compound semiconductor metal-oxide semiconductor field effect transistors (MOSFETs) such as silicon carbide (SiC) MOSFETs offer significantly improved breakdown field and lower on resistance due to their increased bandgap and other key material properties. In addition, the larger bandgap of SiC allows SiC MOSFETs to operate at significantly higher temperatures as compared to silicon-based MOSFETs. A SiC-based power MOSFET may thus be more compact as compared to a silicon-based switching power supply due to its reduced cooling requirements.

SiC MOSFETS are typically n-type metal-oxide semiconductor (NMOS) vertical devices in which the electrons flow from a source at the top of the device to a drain in the bottom of the device. The channel is doped p-type and couples to a p-type body whereas the source is doped n-type. A p-n junction is thus formed between the body and the source. Should the body-to-source p-n junction become forward biased, the MOSFET may be subject to latch-up and other problems. A body contact to the body is thus grounded to prevent the body-to-source p-n junction from becoming forward biased.

### SUMMARY

In accordance with an aspect of the disclosure, a silicon carbide transistor is provided that includes: a source contact having a sidewall, a body beneath a lower surface of the source contact; a body contact coupled to the body, wherein the body has an upper surface extending laterally from the sidewall of the source contact to an upper surface of the body contact; and a silicide layer covering the upper surface of the body contact and the sidewall of the source contact.

In accordance with another aspect of the disclosure, a method of manufacturing a silicon carbide transistor is provided that includes the acts of: forming a body contact in a silicon carbide layer, the body contact extending into the silicon carbide layer from an upper surface of the silicon carbide layer; forming a source contact and a body in the silicon carbide layer, the source contact extending from the upper surface of the silicon carbide layer to the body and extending from a first lateral border to a second lateral border, the first lateral border adjoining the body contact; etching the body contact to remove an entire upper portion of the body contact to form an etched body contact while etching the source contact to remove a partial upper portion to form an etched source contact that extends from a sidewall spaced apart from the body contact to the second lateral border; and forming a silicide layer over the etched body contact and the sidewall of the etched source contact.

In accordance with yet another aspect of the disclosure, a silicon carbide transistor is provided that includes: a source; a source contact having a sidewall; a channel positioned between the source and the source contact, the source contact having an upper surface that is parallel with an upper surface of the channel and with an upper surface of the source; a body contact having an upper surface that is below the upper surface of the source contact and spaced laterally apart from the sidewall; and a silicide layer configured to form a buried contact to the body contact and also configured to cover the sidewall.

These features and additional advantageous features for the disclosed multi-level buck converters may be better appreciated through consideration of the following detailed description.

### BRIEF DESCRIPTION OF THE DRAWINGS

FIG. 1 is a plan view of a traditional planar SiC MOSFET.

FIG. 2 is a cross-sectional view of one-half of the SiC MOSFET of FIG. 1 taken along lines A-A.

FIG. 3 is a cross-sectional view of one-half of the SiC MOSFET of FIG. 1 taken along lines B-B.

FIG. 4 is a plan view of a SiC MOSFET in accordance with an aspect of the disclosure.

FIG. 5 is a cross-sectional view of one-half of the SiC MOSFET of FIG. 4 taken along lines A-A.

FIG. 6 is a cross-sectional view of a SiC layer during the masking and implantation of the p+ doped body contact for the manufacture of a SiC MOSFET in accordance with an aspect of the disclosure.

FIG. 7 is a cross-sectional view of the SiC layer of FIG. 6 following the masking and implantation of the p-doped body for the manufacture of a SiC MOSFET in accordance with an aspect of the disclosure.

FIG. 8 is a cross-sectional view of the SiC layer of FIG. 7 following the masking and implantation of the n+ doped source contact for the manufacture of a SiC MOSFET in accordance with an aspect of the disclosure.

FIG. 9 is a cross-sectional view of the SiC layer of FIG. 8 following the deposition of a carbon cap layer prior to the annealing for the manufacture of a SiC MOSFET in accordance with an aspect of the disclosure.

FIG. 10 is a cross-sectional view of the SiC layer of FIG. 9 following the formation of the gate and the masking of the source contact prior to the wet etching step for the manufacture of a SiC MOSFET in accordance with an aspect of the disclosure.

FIG. 11 is a cross-sectional view of the SiC layer of FIG. 10 following the wet etching of the source contact and the body contact for the manufacture of a SiC MOSFET in accordance with an aspect of the disclosure.

FIG. 12 is a flowchart summarizing a method of manufacture for a SiC MOSFET in accordance with an aspect of the disclosure.

Embodiments of the present disclosure and their advantages are best understood by referring to the detailed description that follows. It should be appreciated that like reference numerals are used to identify like elements illustrated in one or more of the figures.

### DETAILED DESCRIPTION

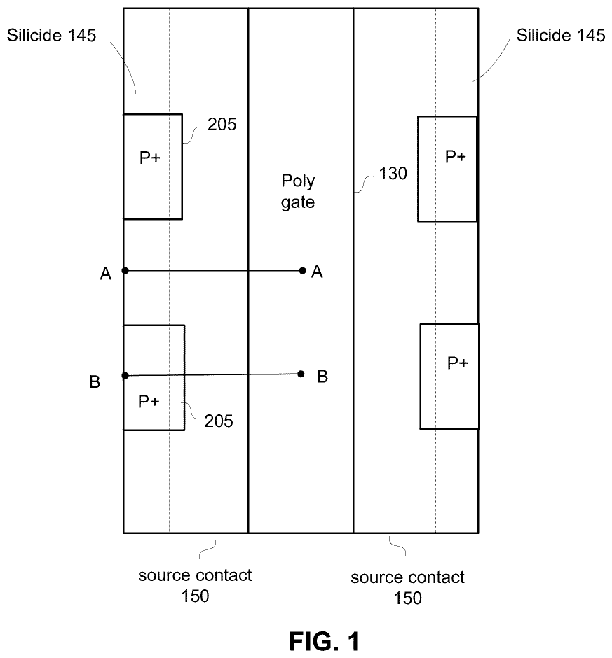

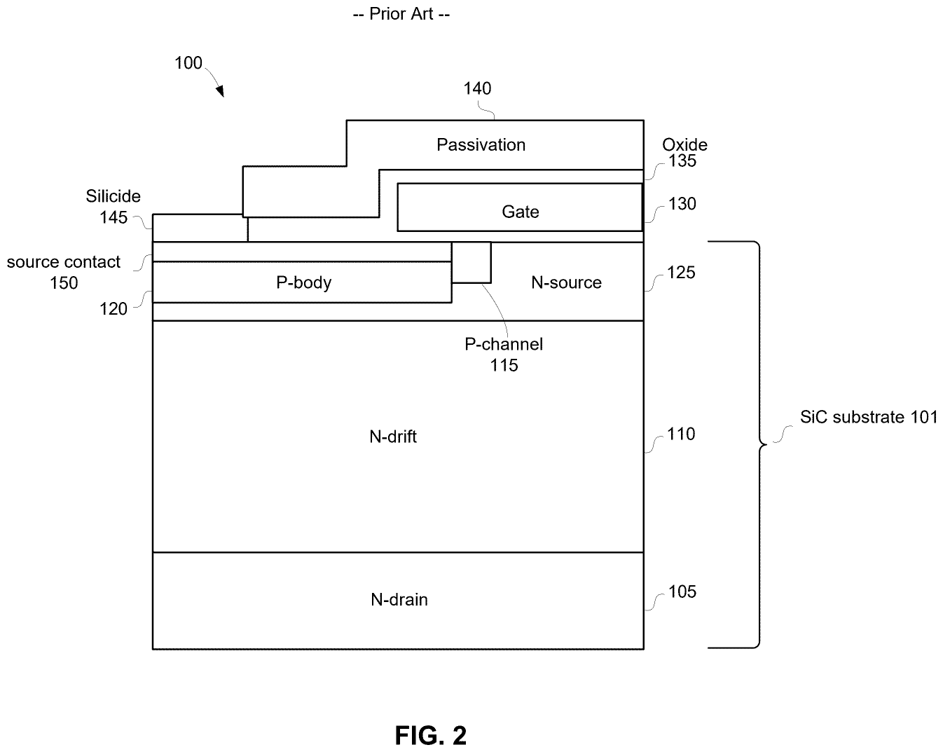

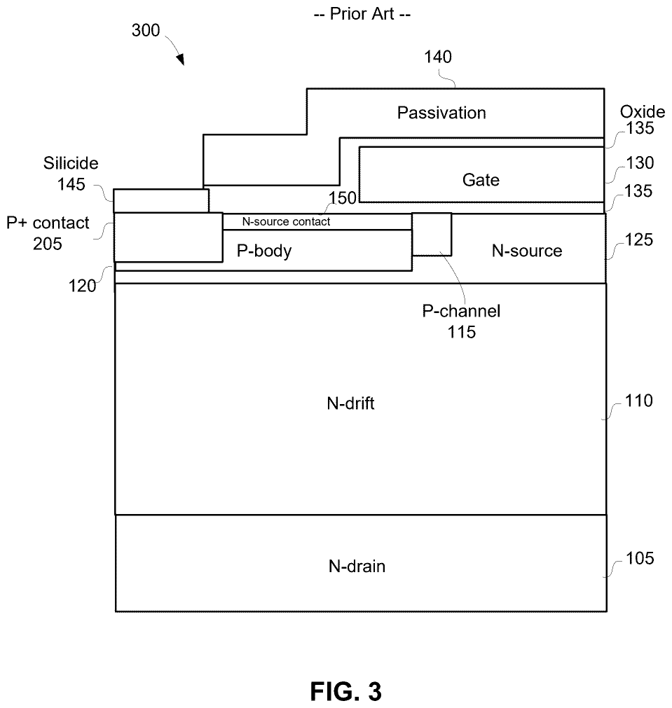

The use of silicon carbide generally forces the device polarity to be n-type metal-oxide semiconductor (NMOS). The following discussion will thus be directed to an improved NMOS SiC MOSFET, but it will be appreciated that the principles disclosed herein are readily applicable to PMOS SIC MOSFETs. The improvements relate to a buried contact for the body that addresses several issues with respect to traditional body contacts for a vertical SiC MOSFET. To provide a better appreciation of the SiC MOSFET improvements disclosed herein, an example conventional SiC MOSFET 100 as shown in plan view in FIG. 1 and in cross-sectional view of the SiC MOSFET 100 along lines A-A in FIG. 2. An additional cross-sectional view of the SiC MOSFET 100 along lines B-B is shown in FIG. 3. Due to the symmetry, only one-half of the SiC MOSFET 100 is shown in the cross-sectional views of FIGS. 2 and 3 as the remaining half would be identical or virtually identical. With respect to FIG. 2, a SiC 101 is doped to form an n-type source which faces an upper surface of an n-type drift region 110. A lower surface of the drift region 110 faces an n-type drain 105 at the bottom of the SiC layer 101. A p-doped channel 115 separates the source 125 from an n-type source contact 150. The channel 115 also has an ohmic contact with a p-doped body 120 that lies below the source contact 150. A gate oxide 135 insulates a polysilicon gate 130 from the channel 115 and the source 125. A passivation layer 140 covers the gate oxide 135 on the upper surface of the gate 130. A silicide layer 145 couples to the source contact 150. With the gate 130 charged to invert the channel 115, a vertical current of electrons may flow from the source contact 150 through the channel 115 to the source 125 and from the source 125 through the drift region 110 and finally to the drain 105.

SiC MOSFET 100 is an example of a planar MOSFET as demonstrated by the planar upper surface of the SiC layer 101. In the following discussion, it will be assumed that the SiC layers disclosed herein such as SiC layer 101 are deposited onto a substrate such as through epitaxial deposition. However, these SiC layers may instead comprise a SiC substrate itself in alternative implementations. As compared to non-planar architectures such as a trench SiC MOSFET, planar SiC MOSFETs benefit from substantially lower manufacturing costs. With respect to the planar upper surface of the SiC layer 101, a P+ doped body contact 205 extends from this upper surface to form an ohmic contact with the body 120 as shown in FIG. 3. The silicide layer 145 that grounds the source contact 150 also grounds the body contact 205. This grounding of the body contact 205 also grounds the body 120 to prevent the p-n junction between the body 120 and the source 125 from becoming forward biased. But the electrons conducting through the source contact 150 to the source 125 cannot conduct through the body contacts 205. Body contacts 205 thus undesirably increase the on-resistance of the SiC MOSFET 100. In addition, the implantation of the body contacts 205 may undesirably implant the side wall of the gate 130.

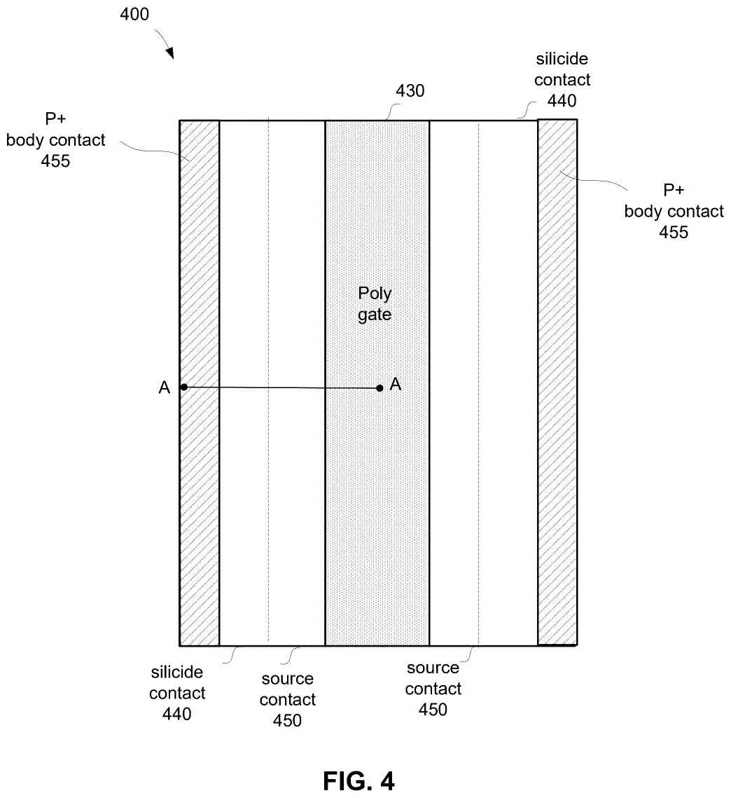

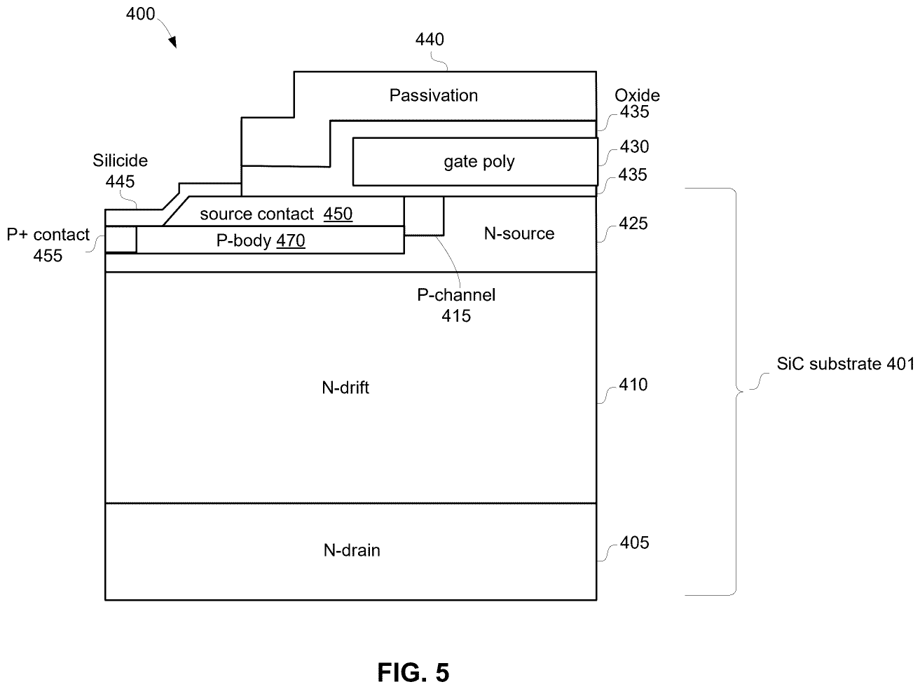

An improved SiC MOSFET 400 is shown in plan view in FIG. 4 and in a cross-sectional view in FIG. 5 along lines A-A of FIG. 4. The SiC MOSFET 100 has an advantageous lowered on-resistance as compared to SiC MOSFET 100 as will be explained further herein. As shown in the cross-sectional view of FIG. 5, a SiC layer 401 includes an n-type source 425, a p-type channel 415, and a p-type body 470 that are arranged analogously as discussed for their counterparts in SiC MOSFET 100. Similarly, an N-type drift region 410 separates the source 425 and an N-type drain 405 analogously as discussed for their counterparts in SiC MOSFET 100. But in SiC MOSFET 400, an N-type source contact 450 has been etched such that a lateral extent of the source contact 450 is less than a lateral extent of the body 470. This same etching of the source contact 450 also etches away an upper portion of p+ doped body contact 455. The height or vertical thickness of the body contact 455 may thus be substantially the same as the height or vertical thickness of the body 470. A silicide layer 445 deposited over an upper surface of the body contact 455 and also over a sidewall and a portion of an upper surface of the source contact 450 is thus forming a buried contact to the body contact 455. The contact is a buried contact because the upper surface of the body contact 455 is lower than the sidewall and upper surface of the source contact 450.

Since the body contact 455 is coupled through a buried contact as compared to the coupling of the silicide layer 445 to the source contact 450, there is no blocking of the electron current through the source 425 by the body contact 455. Referring again to the plan view of FIG. 5, the source contact 450 is positioned on both the left and right sides of a gate 430 (note that FIG. 5 is showing only one-half of a cross-section through MOSFET 400 duc to its symmetry). In the following discussion, it will be assumed that the gate 430 is polysilicon, but it will be appreciated that other suitable conducting materials may be used to form the gate 430 in alternative implementations. The body contact 455 is thus duplicated due to this symmetry as shown in FIG. 4. Note that each body contact 455 has a relatively narrow lateral extent as compared to a lateral extent of the gate 430. Referring again to FIG. 5, the gate 430 is insulated from the source 425, the channel 415, and the source contact 450 by an oxide layer 435. A passivation layer 440 covers the gate 430 and oxide layer 435 analogously as discussed for SiC MOSFET 100.

The etching of the source contact 450 preferably forms a slanted sidewall to increase the surface area that couples to the silicide layer 445. Regardless of whether the sidewall is slanted or not, the silicide layer 445 couples to the sidewall. The electron current from the silicide layer 445 to the source contact 450 may thus conduct not only through the upper surface of the source contact 450 but also through the sidewall. The net result is that the entire cross-section of the source contact 450 may assist in conducting current. But this is not the case for SiC MOSFET 100 as there is no coupling to any sidewall of the source contact 150. Instead, the current from the silicide layer 145 to the source contact 150 must entirely flow through the upper surface of the source contact 150. The current is thus concentrated in the upper surface of the source contact 150 whereas it is distributed more evenly through the source contact 450 in the SiC MOSFET 400. In addition, the body contacts 455 do not interrupt or block the flow of electrons from the source contact 450 to the source 425. In contrast, the body contacts 205 in the SiC MOSFET 100 locally block the flow of electrons in the source contact 150. The more even current distribution along with the lack of current dead zones with respect to the body contacts 455 advantageously lowers the on-resistance and spreading resistance for SiC MOSFET 400 as compared to traditional planar SiC MOSFETS such as SiC MOSFET 100. In addition, SiC MOSFET 400 has improved avalanche capability and improved parasitic bipolar junction transistor suppression as compared to conventional planar SiC MOSFETs such as SiC MOSFET 100.

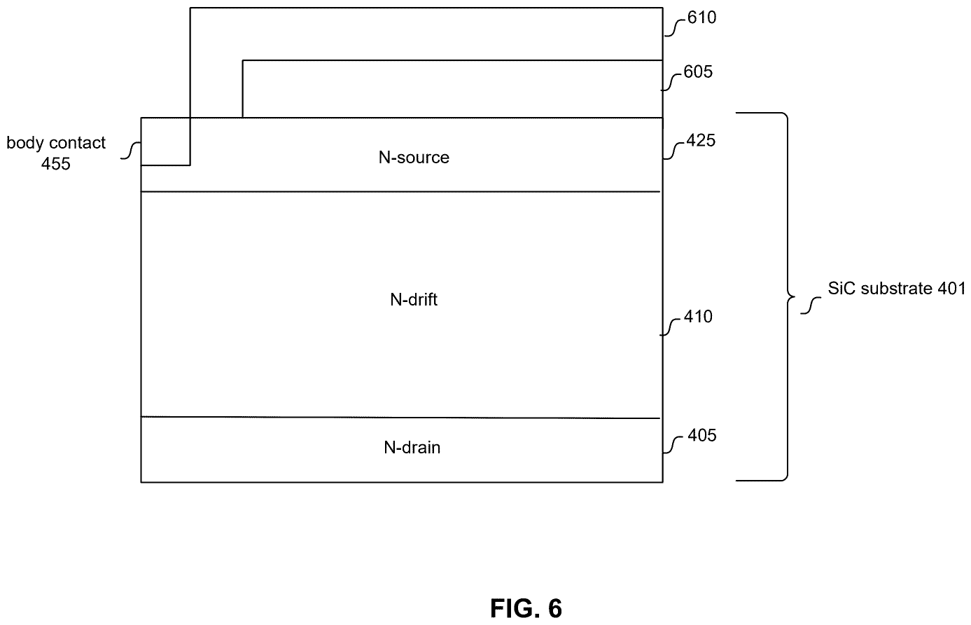

The manufacturing process for SiC MOSFET 400 also leads to several advantages over traditional planar SiC MOSFETs. This manufacturing process will now be discussed in more detail. As shown in FIG. 6, the SiC layer 401 is doped to include the source 425, the drift region 410, and the drain 405 through either a diffusion or implantation process. Referring again to FIG. 4, note that the lateral extent of each body contact 455 is relatively narrow. To assist in the formation of such relatively narrow body contacts 455, the upper surface of the SiC layer 401 is masked with a first hard mask layer 605 as shown in FIG. 6. A second hard mask layer 610 covers the upper surface and the sidewall of the first hard mask layer 605 to advantageously narrow the window in the mask layers for the formation of the body contact 455. In the following discussion, it will be assumed that implantation is used to form the body contact 455 although diffusion may be used in alternative implementations. With the use of both the hard mark layer 605 and the hard mask layer 610, the lateral extent of the body contact 455 may be more tightly controlled. However, it will be appreciated that a single hard mask may be used during the implantation of the body contact 455.

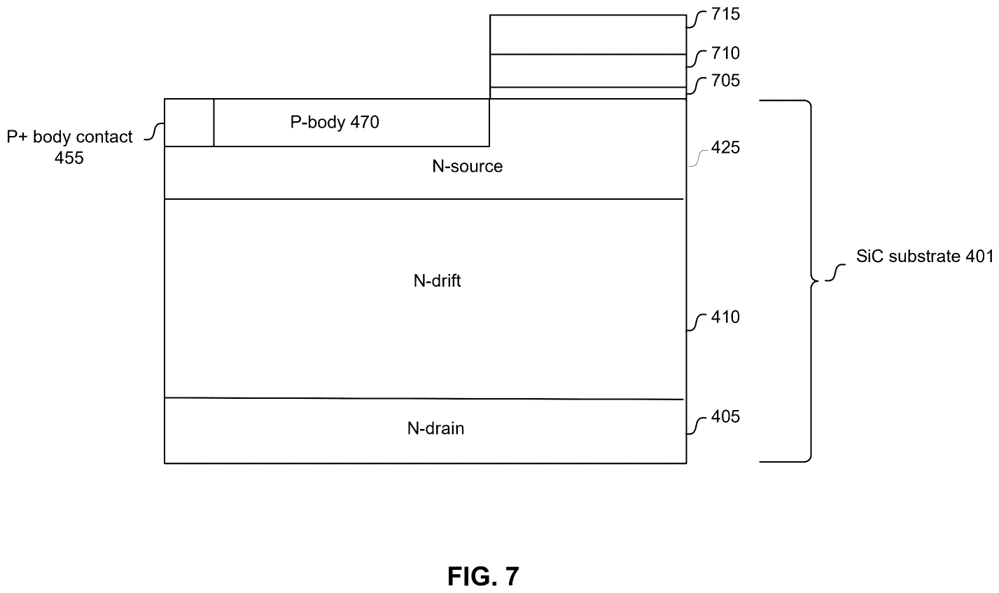

The hard mask layers 605 and 610 are then removed so that the SiC layer 401 may be masked for the formation of the body 470 as shown in FIG. 7. In this implementation, the masking uses a screen oxide layer 705, a first hard mask layer 710, and a second hard mask layer 715 but it will be appreciated that the masking and patterning for the formation of the body 470 may be varied in alternative implementations. With the mask layers 710 and 715 patterned appropriately, p-type ions may be implanted into the SiC layer 401 to form the body 470. Alternatively, diffusion may be used to form the body 470.

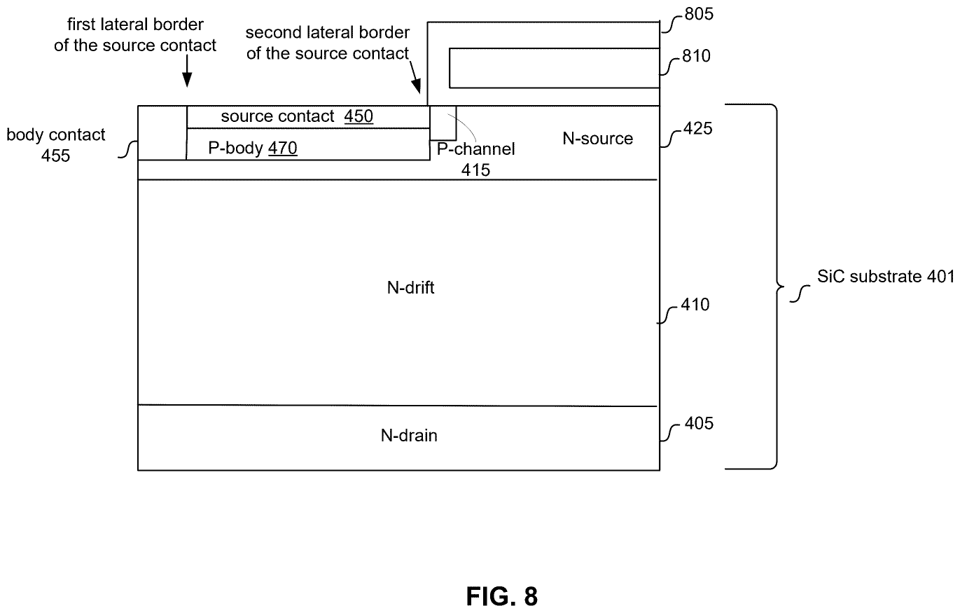

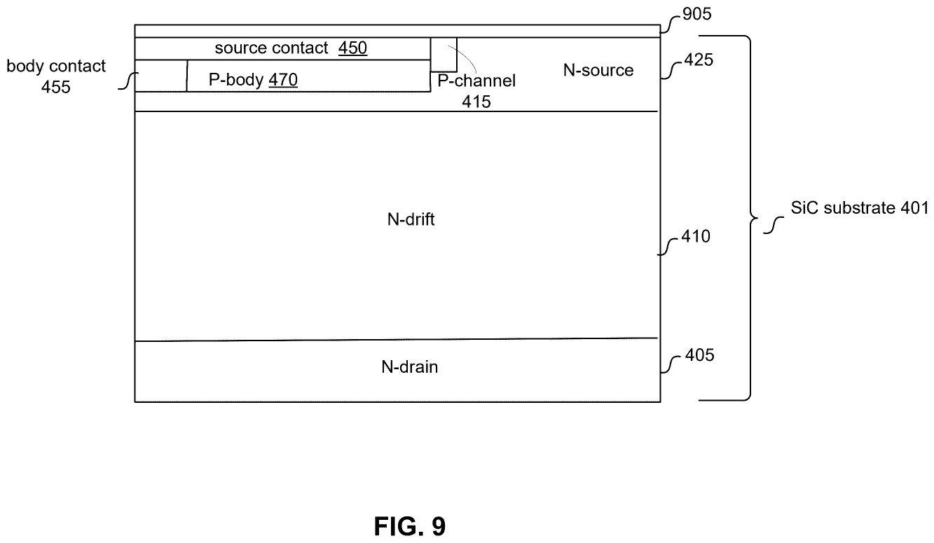

Turning now to FIG. 8, the layer 401 may then be masked with another oxide layer 805 and a hard mask layer 810 that covers a portion of the body 470 that will form the channel 415. The body 470 may then be further implanted followed by an implantation of the source contact 450. The first and second lateral borders of the source contact 450 as shown in FIG. 8 will be discussed further below. Advantageously, the oxide layer 805 and the hard mask layer 810 may then be removed so that the planar SiC layer 401 may then be covered by an appropriate cap layer such as a carbon cap layer 905 as shown in FIG. 9. With the cap layer deposited, the SiC layer 401 may then be annealed at a suitable temperature. But note that such a cap layer will be planar, which aids in its complete removal following the annealing process. In contrast, the cap layer for the SiC MOSFET 100 is non-planar and may thus be subject to partial removal.

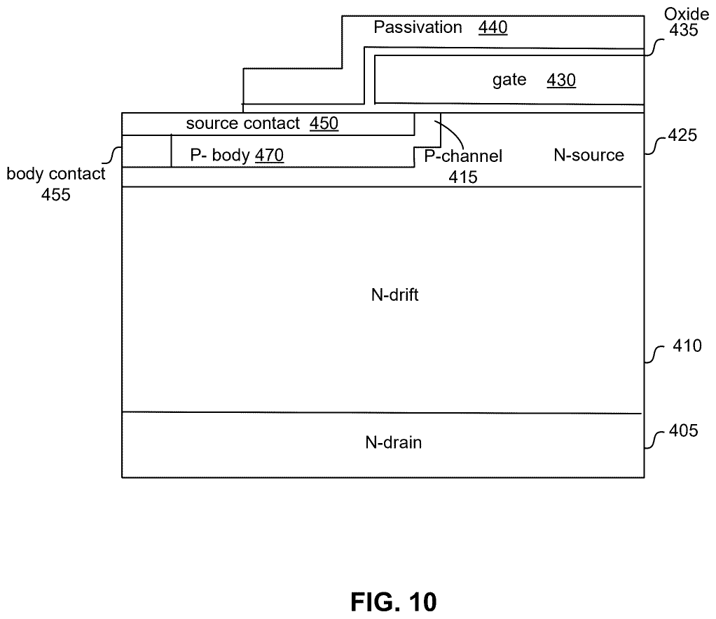

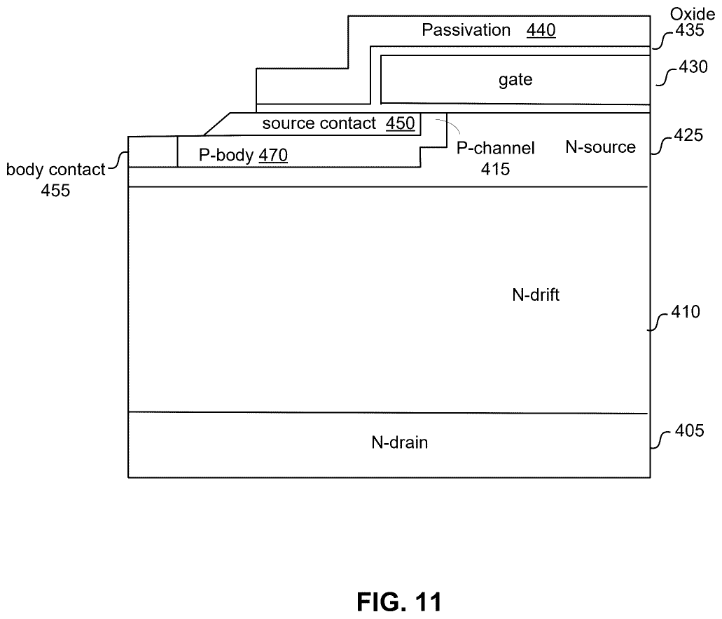

With the annealing completed, the oxide layer 435 and the gate 430 may be formed and covered by the passivation layer 440 as shown in FIG. 10. The passivation layer 440 and oxide layer 435 are patterned to form a window for an etching such as a wet etching of the source contact 450 and the body contact 450. As shown in FIG. 11, a lateral portion of the source contact 450 and an upper portion of the body contact 455 are etched away. After the etching, the source contact 450 may also be denoted as an etched source contact. Similarly, the body contact may also be denoted as an etched body contact. In one implementation, the source contact 450 may extend laterally from a lateral extent of the masking by the passivation layer 440. A sidewall of the source contact 450 advantageously is slanted from vertical by the wet etching so as to increase the surface area for eventual coupling to the silicide layer (not illustrated in FIG. 10).

With the wet etching of the body contact 455 and the source contact 450 completed, the silicide layer 445 as shown in FIG. 5 may be deposited over the upper surface of the body contact 455 as well as the sidewall of the source contact 450 and any exposed upper surface of the source contact 450 to complete the SiC MOSFET 400. The resulting manufacturing process has multiple advantages over that used for conventional planar SiC MOSFETs such as SiC MOSFET 100. For example, the implantation of the body contact 205 in SiC MOSFET 100 requires an extra surface implant that is not necessary for the formation of SiC MOSFET 400 since the upper portion of the body contact 455 is etched away in the embodiments disclosed herein. Moreover, the surface implant in SiC MOSFET 100 increases the possibility that a sidewall of the SiC MOSFET 100 may be undesirably implanted from the surface implant. In contrast, the implantation of the body contact 455 occurs before the formation of the source contact 450 so no sidewall contamination may occur. In addition, there is no need for a surface implant with respect to the body contact 455 as its upper surface is etched away.

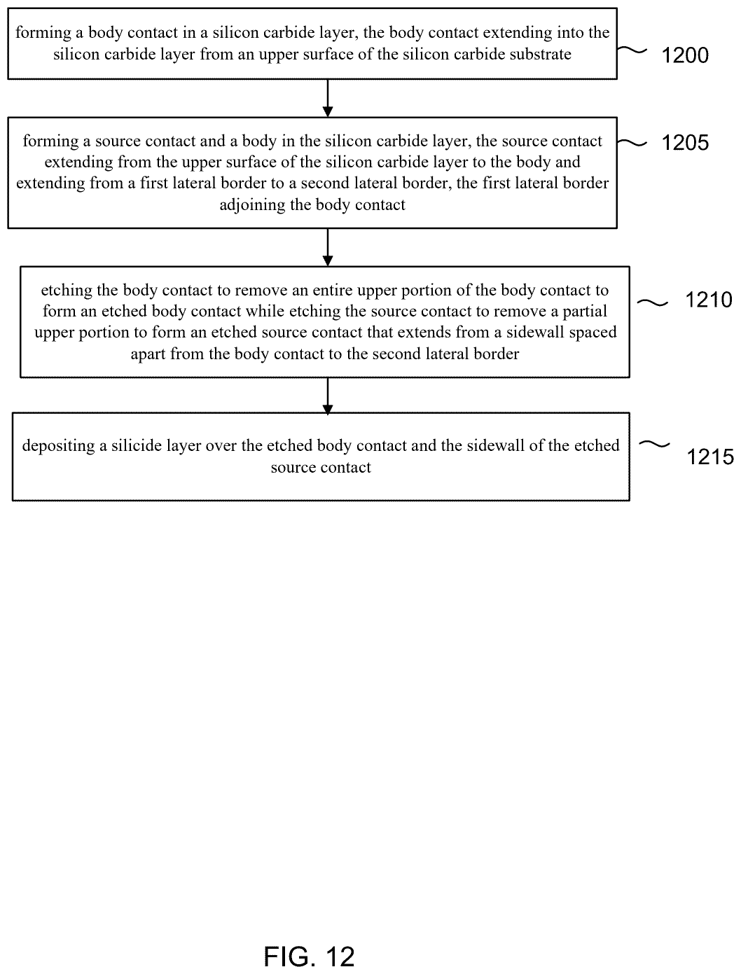

A method of manufacturing a SiC MOSFET such as SiC MOSFET 400 will now be summarized with respect to the flowchart of FIG. 12. The method includes an act 1200 of forming a body contact in a silicon carbide layer, the body contact extending into the silicon carbide layer from an upper surface of the silicon carbide layer. An example of act 1200 is the implantation of the body contact 455 as discussed with regard to FIG. 6. The method also includes an act 1205 of forming a source contact and a body in the silicon carbide layer, the source contact extending from the upper surface of the silicon carbide layer to the body and extending from a first lateral border to a second lateral border, the first lateral border adjoining the body contact. An example of act 1205 is the implantation of the source contact 450 and the body 470 as discussed with regard to FIG. 8. As shown in FIG. 8, the source contact 450 laterally extends from a first lateral border to a second lateral border. The first lateral border adjoins the body contact 455. The method further includes an act 1210 of etching the body contact to remove an entire upper portion of the body contact to form an etched body contact while etching the source contact to remove a partial upper portion to form an etched source contact that extends from a sidewall spaced apart from the body contact to the second lateral border. The etching of the source contact 450 and the body contact 455 as discussed with respect to FIGS. 9-11 is an example of act 1210. Finally, the method includes an act 1215 of depositing a silicide layer over the etched body contact and the sidewall of the etched source contact. The deposition of the silicide layer 445 as discussed with regard to FIG. 4 is an example of act 1215. Note that whether the silicide layer 445 covers an upper surface of the source contact 450 depends upon whether the source contact 450 extends laterally from a lateral edge of the passivation masking layer 440. In some implementations, the etching of the source contact 450 may etch it back to the lateral extent of the passivation masking layer 440. In that case, the silicide layer 445 would contact only the sidewall of the source contact 450. But in other implementations in which the source contact 450 is not etched back to the lateral edge of the passivation masking layer 440, the silicide layer 445 also covers the exposed portion of the upper surface of the source contact 450.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. A silicon carbide transistor, comprising:
a source contact having a sidewall,
a body beneath a lower surface of the source contact;
a body contact coupled to the body, wherein the body has an upper surface extending laterally from the sidewall of the source contact to an upper surface of the body contact; and
a silicide layer covering the upper surface of the body contact and the sidewall of the source contact.

2. The silicon carbide transistor of claim 1, further comprising:
a source having an upper surface that is linearly aligned with an upper surface of the source contact; and
a channel having an upper surface that is linearly aligned with the upper surface of the source contact and of the source, wherein channel is positioned between the source and the source contact.

3. The silicon carbide transistor of claim 2, further comprising:
a drift region below the source, and
a drain below the drift region.

4. The silicon carbide transistor of claim 3, wherein the source contact, the source, the drift region, and the drain are all doped n-type, and wherein the body, the channel, and the body contact are all doped p-type.

5. The silicon carbide transistor of claim 4, wherein the source contact is doped more heavily than the source, and wherein the body contact is doped more heavily than the body.

6. The silicon carbide transistor of claim 1, wherein the silicide layer also covers a portion of an upper surface of the source contact.

7. The silicon carbide transistor of claim 1, wherein the sidewall is a slanted sidewall.

8. The silicon carbide transistor of claim 7, wherein the slanted sidewall that extends laterally from an upper surface of the source contact towards the body contact.

9. The silicon carbide transistor of claim 2, further comprising:
a gate separated from the upper surface of the channel by an oxide layer, wherein the gate has a first lateral extent that is greater than a lateral extent of the body contact.

10. The silicon carbide transistor of claim 9, wherein the gate comprises polysilicon.

11. A method of manufacturing a silicon carbide transistor, comprising:
forming a body contact in a silicon carbide layer, the body contact extending into the silicon carbide layer from an upper surface of the silicon carbide layer;
forming a source contact and a body in the silicon carbide layer, the source contact extending from the upper surface of the silicon carbide layer to the body and extending from a first lateral border to a second lateral border, the first lateral border adjoining the body contact;
etching the body contact to remove an entire upper portion of the body contact to form an etched body contact while etching the source contact to remove a partial upper portion to form an etched source contact that extends from a sidewall spaced apart from the body contact to the second lateral border; and
depositing a silicide layer over the etched body contact and the sidewall of the etched source contact.

12. The method of claim 11, wherein forming the body contact comprises implanting the body contact into the silicon carbide layer, and wherein forming the source contact and the body comprises implanting the source contact and the body into the silicon carbide layer.

13. The method of claim 12, wherein etching the body contact and the source contact comprises wet etching the body contact and the source contact.

14. The method of claim 11, further comprising:
depositing the silicide layer over a portion of an upper surface of the etched source contact.

15. The method of claim 13, wherein the wet etching of the source contact causes the sidewall to be a slanted sidewall.

16. A silicon carbide transistor, comprising:
a source;
a source contact having a sidewall;
a channel positioned between the source and the source contact, the source contact having an upper surface that is linearly aligned with an upper surface of the channel and with an upper surface of the source;
a body contact having an upper surface that is below the upper surface of the source contact and spaced laterally apart from the sidewall; and
a silicide layer configured to form a buried contact to the body contact and also configured to cover the sidewall.

17. The silicon carbide transistor of claim 16, wherein the buried contact to the body contact covers the upper surface of the body contact.

18. The silicon carbide transistor of claim 16, further comprising:
a body positioned below the source contact and having an ohmic contact with the body contact.

19. The silicon carbide transistor of claim 18, further comprising:
a drift region below the source, and
a drain below the drift region.

20. The silicon carbide transistor of claim 19, wherein the source contact, the source, the drift region, and the drain are all doped n-type, and wherein the body, the channel, and the body contact are all doped p-type.
